(19) United States
(12) Patent Application Publication
(10) Pub. No.: US 2026/0175283 A1
(43) Pub. Date: Jun. 25, 2026

(54) Precision System and Assembling Method Thereof

(71) Applicant: BRIGHTEST TECHNOLOGY TAIWAN CO., LTD., Hsinchu County (TW)

(72) Inventors: Jie Zhang, Santa Clara, CA (US); Kuo-Feng Tseng, Santa Clara, CA (US); Zhonghua Dong, Santa Clara, CA (US)

(73) Assignee: BRIGHTEST TECHNOLOGY TAIWAN CO., LTD., Hsinchu County (TW)

(21) Appl. No.: 19/056,781

(22) Filed: Feb. 19, 2025

Related U.S. Application Data
(63) Continuation-in-part of application No. 18/988,956, filed on Dec. 20, 2024.

(51) Int. Cl. B21D 51/24

(52) U.S. Cl. CPC B21D 51/24

(57) ABSTRACT

A precision system includes a chamber and an enclosure. The chamber includes a first wall and a second wall to create a first accommodation space. At least one precision part is mounted on the first wall inside the first accommodation space. The enclosure and the chamber are assembled to create a second accommodation space. The second accommodation space between the enclosure and the first wall connects to the first accommodation space. Deformation of the first wall is substantially less than deformation of the second wall or the enclosure after pressure in the first accommodation space becomes different from pressure outside the precision system.

### CROSS REFERENCE TO RELATED APPLICATIONS

This application is a continuation-in-part of U.S. application Ser. No. 18/988,956, filed on Dec. 20, 2024. The content of the application is incorporated herein by reference.

### BACKGROUND OF THE INVENTION

### 1. Field of the Invention

The present invention relates to a precision system and an assembling method thereof, and more particularly, a precision system and an assembling method thereof that ensure the alignment of precision components.

### 2. Description of the Prior Art

The high pressure difference between vacuum and the atmosphere causes significant deformation on a vacuum vessel. This deformation can transfer from the vacuum vessel to precision parts mounted inside it, leading to changes in high-precision alignment or damage to those precision parts. Further, there is the problem that scattered particles discharged from materials (e.g., the precision parts) may contaminate the surfaces of the precision parts. Consequently, the prior art vacuum vessel is not necessarily used favorably.

### SUMMARY OF THE INVENTION

It is therefore a primary objective of the present application to provide a precision system and an assembling method thereof, to improve over disadvantages of the prior art.

An embodiment of the present invention discloses a precision system comprising a chamber, comprising a first wall and a second wall to create a first accommodation space, wherein at least one precision part is mounted, or is to be mounted, on the first wall inside the first accommodation space; and an enclosure, wherein the enclosure and the chamber are assembled, or are to be assembled, to create a second accommodation space; wherein the second accommodation space between the enclosure and the first wall connects to the first accommodation space; wherein deformation of the first wall is substantially less than deformation of the second wall or the enclosure after pressure in the first accommodation space becomes different from pressure outside the precision system.

An embodiment of the present invention discloses an assembling method, for a precision system, comprising mounting at least one precision part on a first wall inside a chamber, wherein the chamber comprises the first wall and a second wall to create a first accommodation space; and assembling an enclosure and the chamber of the precision system to create a second accommodation space; wherein the second accommodation space between the enclosure and the first wall connects to the first accommodation space; wherein deformation of the first wall is substantially less than deformation of the second wall or the enclosure after pressure in the first accommodation space becomes different from pressure outside the precision system.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic diagrams of precision systems according to embodiments of the present invention.

FIGS. 4-10 are schematic diagrams of a precision system according to an embodiment of the present invention.

### DETAILED DESCRIPTION

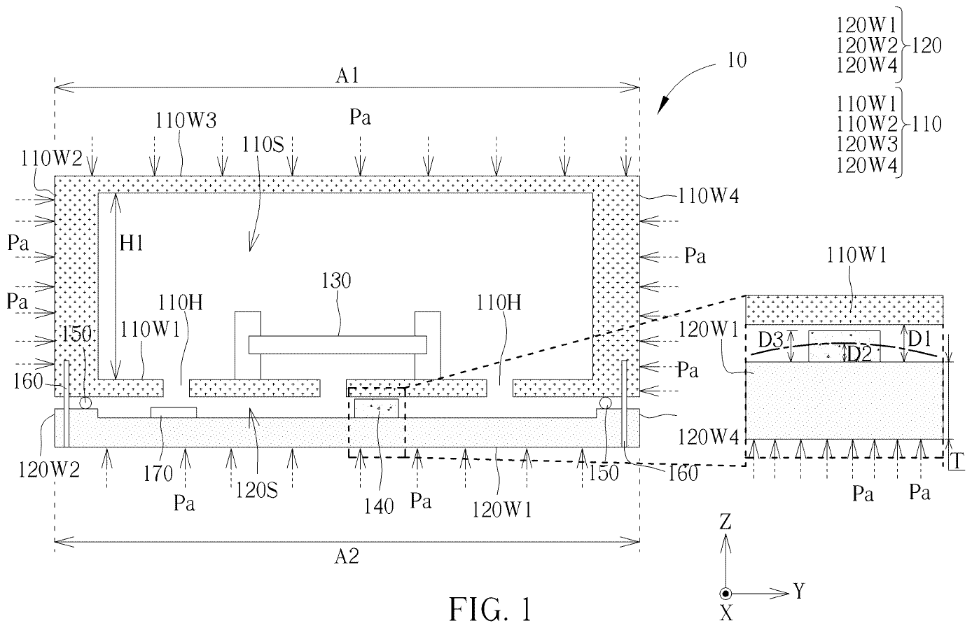

FIG. 1 is a schematic diagram of a precision system 10 according to an embodiment of the present invention. The precision system 10 comprises a chamber 110 and an enclosure 120. Various precision parts 130 (e.g., a motion stage, a wafer stage, an inspection stage, a semi-conductor device or an optical component) are mounted on a bottom wall 110W1 of the chamber 110.

Deformation of the wall 110W1 should be negligible, such that the relative or absolute positions of the precision parts 130 remain(s) unchanged. Specifically, walls 110W1-110W4 of the chamber 110 form a (first) accommodation space 110S. Inside the accommodation space 110S, the precision parts 130 are carefully positioned, aligned, and oriented with precision to maintain their intended relationships (e.g., alignment along an optical path). If the wall 110W1, which serves as the mounting base for the precision parts 130 and is fixed integrally or directly to the chamber 110, deforms, the relative positions of the precision parts 130 may alter.

Usually, after the precision parts 130 are set precisely on the wall 110W1, the pressure in the accommodation space 110S may change and become different from the external pressure outside the precision system 10. For example, the accommodation space 110S may be evacuated to create a vacuum. Alternatively, the accommodation space 110S may be filled with non-solid substance(s) (e.g., gas, inert gas, Helium, Argon, or a substance of higher ionization energy) to create a pressure (e.g., 10 torr) higher than vacuum. In other words, the pressure of the accommodation space 110S can range from vacuum pressure and a pressure higher than the atmospheric pressure Pa, while the external pressure is the atmospheric pressure Pa. If this pressure difference arises after the alignment, deformation may occur and cause misalignment of the precision parts 130.

The enclosure 120 may enclose the wall 110W1 to withstand the atmospheric pressure Pa, originally applied on the wall 110W1, thereby preventing significant deformation of the wall 110W1. Besides, a (second) accommodation space 120S may be formed between the enclosure 120 and the wall 110W1 when the enclosure 120 and the chamber 110 are assembled. The accommodation space 120S helps to prevent deformation of the enclosure 120 from exerting effect on the wall 110W1. In other words, the wall 110W1, sandwiched between the accommodation spaces 110S and 120S, is effectively protected, and hence the deformation of the wall 110W1 is substantially less than the deformation of the enclosure 120 (or the wall(s) 110W2 . . . 110W4 of the chamber 110). Therefore, the enclosure 120 serves as an atmospheric-pressure-deformation absorption layer.

To minimize the net pressure applied to the wall 110W1, the pressure difference between the accommodation spaces 110S and 120S is kept no greater than the pressure difference between the accommodation space 110S and the atmospheric pressure Pa. To achieve an appropriate pressure difference between the accommodation spaces 110S and 120S, the accommodation spaces 110S and 120S may be interconnected, for example, via one or more through holes 110H, located on the wall 110W1. Alternatively, both the accommodation spaces 110S and 120S may be maintained at the same pressure (e.g., vacuum), such that their pressure difference is minimized. As a result, the wall 110W1 remains unaffected by the pressure difference between the interior and exterior of the precision system 10, which dispenses with the need for re-adjusting the previously-adjusted optical alignment after pressure changes. The accommodation spaces 120S is served as a buffer layer, absorbing deformations caused by atmospheric conditions.

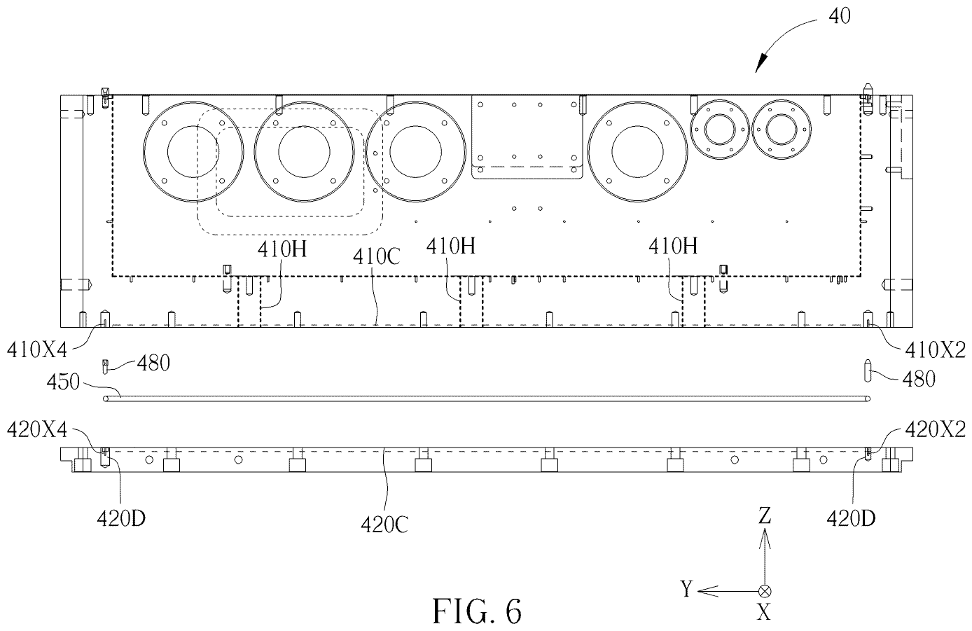

To enhance protection, a wall 120W1 of the enclosure 120 is less strengthened, while the wall 110W1 parallel to the wall 120W1 is reinforced. As shown in FIG. 1, the (third) wall 120W1 may be thicker than the (first) wall 110W1, any of the (second) walls 110W2-110W4, or the height D1 of the accommodation space 120S. However, the wall 120W1 may be thinner than the wall 110W1, which supports the precision parts 130, as the wall 120W1 is designed to deform (e.g., FIG. 6). Alternatively, the material of the (integrally-formed) enclosure 120 may differ from that of the (integrally-formed) chamber 110. The stiffness of the wall 110W1 may be no less than that of the wall 120W1.

The enclosure 120 is outside the chamber 110, as shown in FIG. 1. Comparing to a similar deformation absorption layer/mechanism placed inside a chamber, the deformation absorption enclosure 120 outside the chamber 110 is subject to fewer location constraints. For example, the deformation absorption enclosure 120 can be positioned within the area of the minimum pressure deformation. Alternatively, the location of the deformation absorption enclosure 120 is not restricted by or dependent on the locations of the precision parts 130. In other words, the enclosure 120 offers greater flexibility in terms of location, size, and shape. Therefore, the external configuration of the deformation absorption enclosure 120 simplifies the design, the service, the repairing, and the assembling processes of the enclosure 120 and the chamber 110 because they are separable and independence individuals.

The geometrical features of the enclosure 120 may vary as long as the enclosure 120 is able to offer protection. For example, in FIG. 1, the maximum cross-section area A2 of the enclosure 120 is substantially equal to the maximum cross-section area A1 of the chamber 110. Alternatively, the maximum cross-section area A2 is larger than the maximum cross-section area A1, allowing the chamber 110 to be fully encased within the enclosure 120 (e.g., walls 120W2 and 120W4). Besides, the height D1 of the accommodation space 120S in FIG. 1 is smaller than the height H1 of the accommodation space 110S. For example, the height H1 may be substantially, for example, 10 times greater than the height D1, but this ratio is not strictly limited and the height D1 can be made much larger if necessary.

To minimize deformation of the wall 110W1, as shown in FIG. 1, the precision system 10 may further comprise pad(s) 140, disposed on the wall 120W1 within the accommodation space 120S. Each pad 140 remains separated from the chamber 110 until the pressure in the accommodation space 110S drops (e.g., approaches to vacuum pressure) or rises significantly. For example, as shown in the inset of FIG. 1, the atmospheric pressure Pa (indicated by the dashed arrows) causes deformation of the wall 120W1, altering its original shape (solid lines) into a bulging one (the dash-dot line). However, the pad(s) 140 support(s) the chamber 110 and the enclosure 120, ensuring the enclosure 120 remains at a sufficient distance from the chamber 110. In this manner, the pressure difference may cause deformation of the wall 120W1, but the wall 110W1 may not be subject to bending stress.

The size of each pad 140 is designed to provide enough flexibility and buffer against potential deformation of the enclosure 120. For example, the dimensions of the pad 140 may satisfy the equation D3×0.85=D1−D2, where D3 represents the thickness of the pad 140 without deformation, D1 represents (the height of the accommodation space 120S) or the distance between the walls 110W1 and 120W1, and D2 represents simulated deformation of the wall 120W1. The simulated deformation D2 may be proportional to 1/T³, where T represents the thickness of the wall 120W1. Deformation of the wall 120W1 less than the simulated deformation D2 is reversible/elastic/impermanent, allowing the wall 120W1 to return to the original shape; deformation of the wall 120W1 exceeding the simulated deformation D2 may compromise the seal between the chamber 110 and the enclosure 120, potentially causing leakage. The simulated deformation D2 may be designed to remain just below the yield point of the wall 120W1. The ratio of the simulated deformation D2 (e.g., 0.25 millimeters) to the distance D1 (e.g., 2 millimeters) may be in the range of 10% to 15%.

The pad(s) 140 may also contribute to vibration attenuation. The pad 140 may comprise or act as rubbers or other elastic materials. Alternatively, the damping coefficient of the pad 140 is higher than the damping coefficient of the wall 110W1 or the 120W1 alone. As a result, each pad(s) 140 may enhance the damping of the wall 110W1 or 120W1, which causes vibration energy loss and reduces the vibration due to lack of air flow damping on the wall 110W1. As the damping of the chamber 110, the enclosure 120, or the precision parts 130 increases, the vibration diminishes more rapidly, thereby improving the stability of the precision parts 130. Therefore, the pad 140 serves as a vibration damper.

The thermal conductivity of the pad(s) 140 may be high to reduce the thermal resistance between internal component(s) (e.g., the wall 110W1 or the precision parts 130) and outer surfaces (e.g., the wall 120W1). For example, the pad's thermal conductivity is higher than the thermal conductivity of vacuum or air. As a result, even though the thermal conduction of air or vacuum is poor, thermal energy generated inside the chamber 110 can be dissipated not only via thermal radiation but also through direct conduction facilitated by the pad(s) 140. Therefore, the pad 140 serves as a thermal pad.

To ensure proper ventilation, the arrangement of the holes 110H and the pad(s) 140 is carefully planned. For example, the projection of a pad 140 onto a wall (e.g., 110W1 . . . or 120W1) do not overlap the projection of a hole 110H onto the wall, although the pad 140 may be positioned close to the hole 110H to improve structural strength.

To achieve particle reduction or control, as shown in FIG. 1, the precision system 10 may further comprise particle reducer(s) 170, disposed on the wall 120W1 within the accommodation space 120S. The particle reducer 170 may be a (broad) electrode or comprise two parallel plates with applied voltage(s). The particle reducer 170 can attract micron/submicron/nanoscale particles (e.g., charged contaminants, electrons, ions, neutral particles, or debris) to prevent the tiny particles suspended in space from sticking to component, becoming trapped by radiation (e.g., laser), or contaminating the space. In other words, the accommodation space 120S serves as particle collection pocket.

Each particle reducer 170 may be strategically disposed corresponding to one hole 110H, such that the tiny particles traveling from the accommodation space 110S can be immediately captured by the particle reducer 170 before dispersing back into the accommodation space 110S. As shown in FIG. 1, the particle reducer 170 is located on the wall 120W1 and in close proximity to the hole 110H. The projection of the particle reducer 170 onto the wall 120W1 may be larger than, aligned to, overlaps, or completely covers the projection of the hole 110H onto the wall 120W1, enhancing its effectiveness in capturing particles. Alternatively, the particle reducer 170 is located on the bottom surface of the wall 110W1 and surrounds the hole 110H.

To repair or clean the particle reducer 170, fastener(s) 160 can be removed, allowing the enclosure 120 to be detached and moved away from the chamber 110. Cleaning the particle reducer 170 is much easier when the absorption enclosure 120 is located outside the chamber 110.

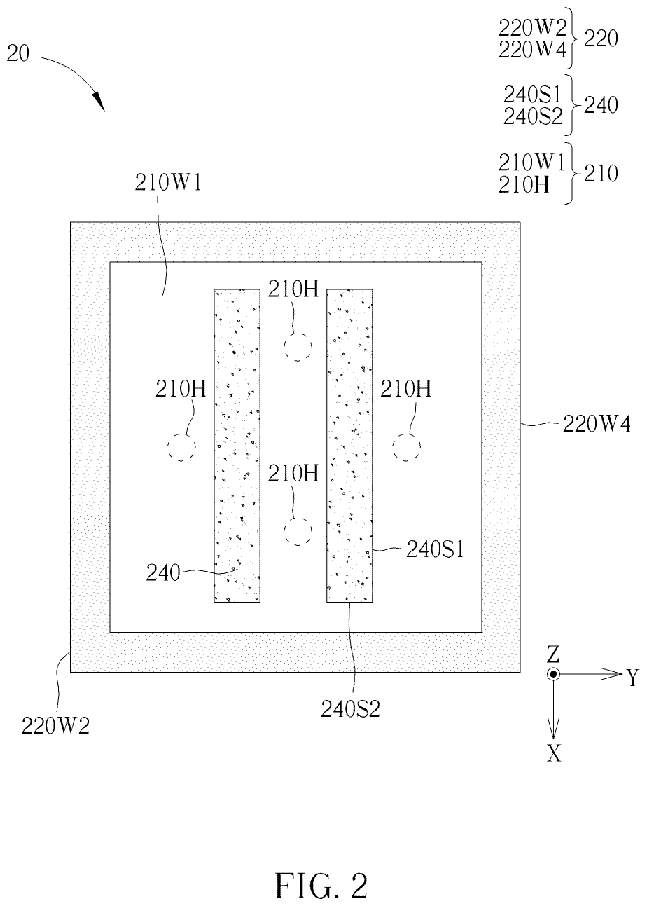

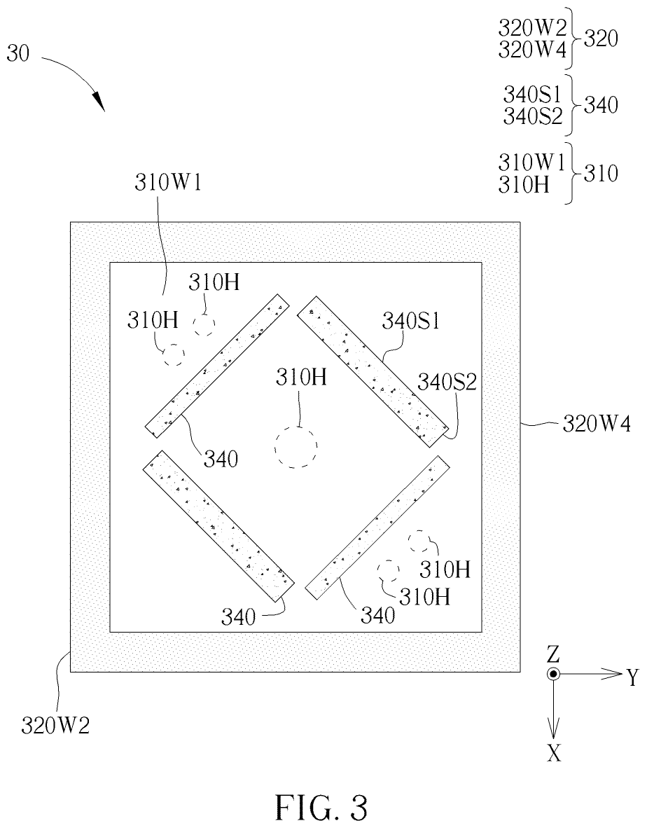

FIG. 1 only illustrates one pad 140 and three holes 110H. However, the precision system 10 may comprise more pads 140 as long as the pads 140 do not create uneven pressure distribution within the accommodation space 120S. Similarly, additional holes 110H may be added to enhance ventilation. For example, FIGS. 2-3 are schematic diagrams of precision systems 20 and 30, which may be implemented using the precision system 10, according to embodiments of the present invention. Features shown in one of FIGS. 2 and 3 can be combined with or applied to the other, provided they do not contradict, unless otherwise indicated.

FIG. 2 illustrates the top-view of a chamber 210, an enclosure 220, and pads 240 of the precision system 20.

The shape, size, or number of the pad 240 is designed to buffer against potential deformation of the enclosure 220. For example, the pad 240 does not cover a wall 220W1 of the enclosure 220 entirely. Instead, several small pads 240 are distributed across the wall 220W1. Besides, the pad 240 may have a bar shape, with a side 240S1, parallel to the X axis, being longer than a side 240S2 or any side parallel to the Z axis. Under deformation, the pad 240 contracts in the Z direction but expands the pad 240 in the X or Y direction. The Poisson's ratio of the pad 240 falls within the range of 0.4 to 0.5, ensuring optimal properties.

The shape, size, or number of the holes 210H may vary according to the required degree of ventilation. As shown in FIG. 2, there are four circular holes 210H. The diameter of the hole 210H is smaller than the side 240S1 or 240S2, and the maximum cross-section area of the pad 240 is larger than the size of the hole 210H.

For example, FIG. 3 illustrates a wall 310W1 of a chamber 310, which comprises five holes 310H of different sizes and four pads 340 of different dimensions. The hole 310H may have the diameter larger than a side 340S2 of the pad 340. Besides, the density of the holes 310H varies across the wall 310W1. For example, the density near the edge of the wall 310W1 is higher than that near the center of the wall 310W1. The pads 340 may not parallel to a wall 320W2.

The holes 310H or the pads 340 may be arranged axial-symmetrically with respect to the symmetrical axes of the wall 310W1 or rotational-symmetrically with respect to the center of the wall 310W1. Alternatively, the arrangement of the pads 340 exhibits symmetry to enhance structural stability while the arrangement of the holes may be asymmetric, tailored to the distribution of the precision parts (e.g., 130).

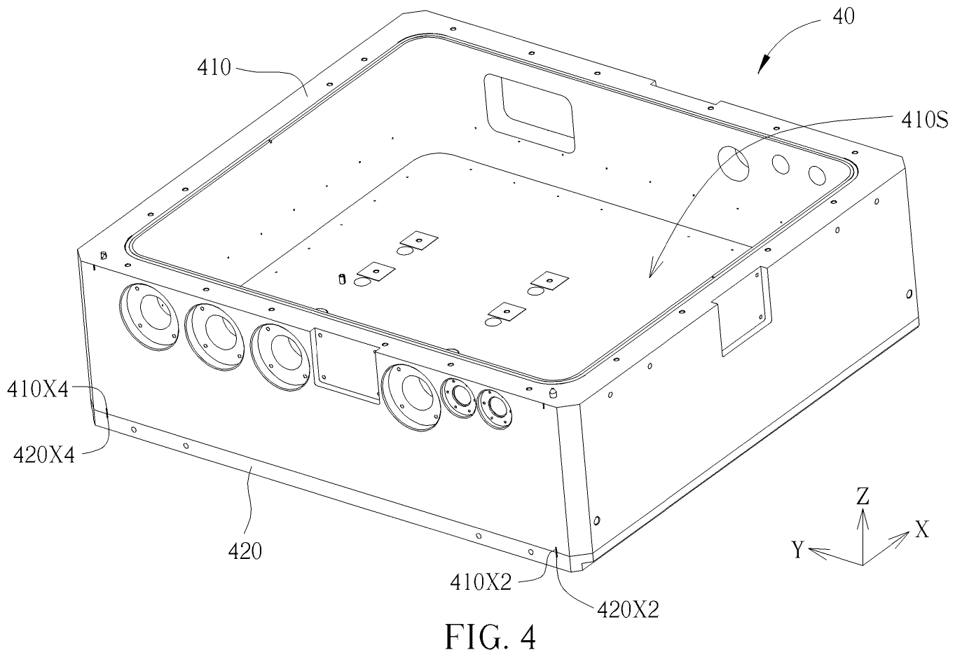

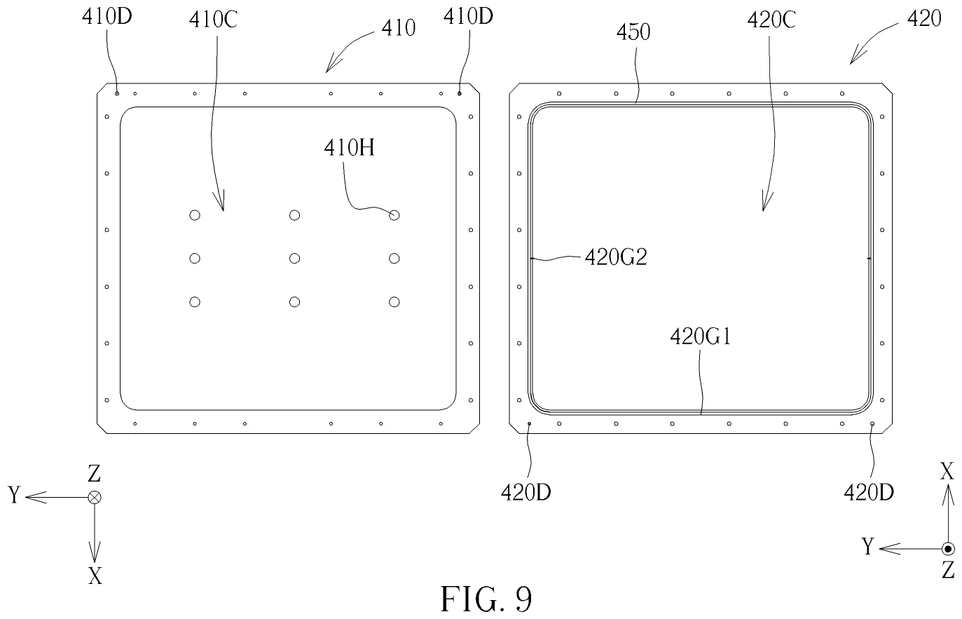

FIGS. 4-10 are schematic diagrams of a precision system 40, which may be implemented using the precision system 10, according to an embodiment of the present invention. As describe above, a bottom wall 420W1 of an enclosure 420 may bear the pressure difference across it and deform, thereby shielding a bottom wall 410W1 of a chamber 410 and precision parts (e.g., 130) on the bottom wall 410W1 from the effects of the atmospheric pressure Pa. In other words, although the wall 420W1 is deformed, misalignment will not be caused since the atmospheric pressure Pa does not act directly on the wall 410W1.

FIG. 4 illustrates the assembly process of the chamber 410 (e.g., a bottom chamber) and the enclosure 420 of the precision system 40 (e.g., a vacuum precision instrument, an inspection device, an aligner, or a semiconductor equipment). When connected to each other, as shown in FIG. 4, the mating chamber 410, which comprises an accommodation space 410S, and the mating enclosure 420 are assembled into a unified device, and a concavity 410C of the chamber 410 and a concavity 420C of the enclosure 420 form an accommodation space 420S. The enclosure 420 may be secured to the chamber 410 using fastener(s) 460 (e.g., screw(s)).

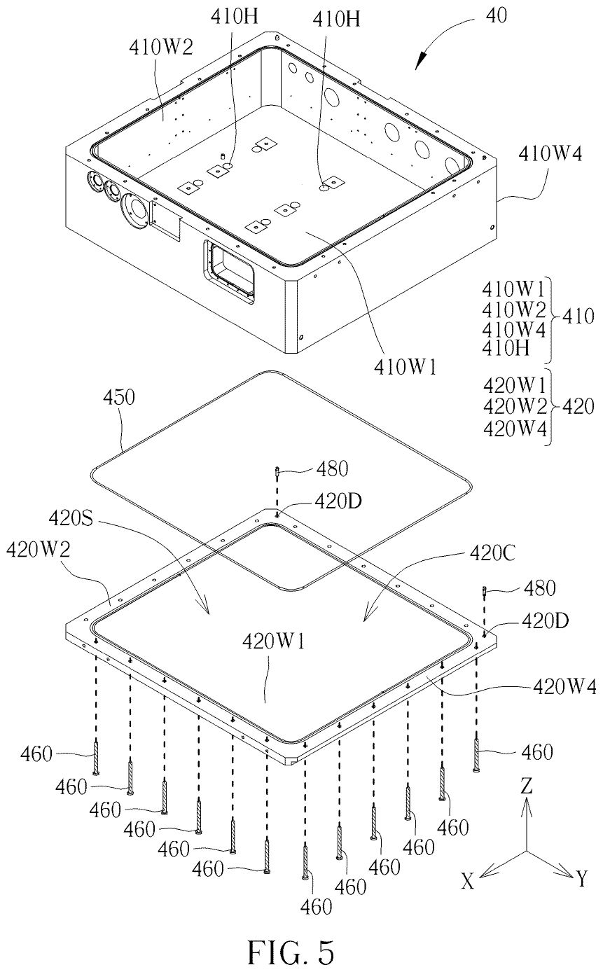

FIG. 5 illustrates the disassembly process of the chamber 410 and the enclosure 420. When the chamber 410 and the enclosure 420 are disconnected as shown in FIG. 5, particle reducer(s) (e.g., 170) located on the wall 420W1 can be easily removed for repairing, replacement, or routine maintenance.

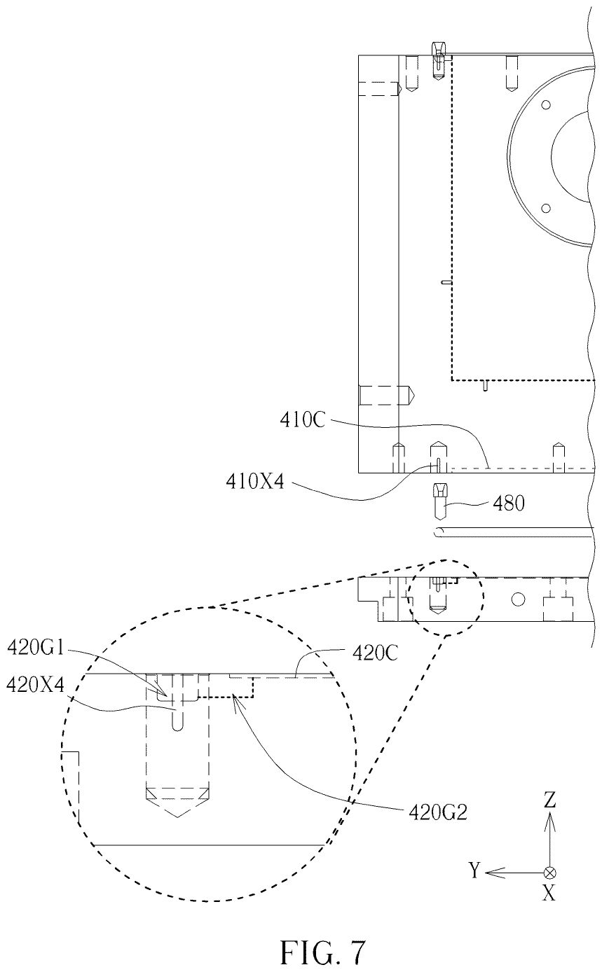

As shown in FIGS. 6 and 7, which illustrate a side-view of the precision system 40, the precision system 40 comprises a seal member 450 (e.g., an O-ring vacuum seal) to ensure a secure seal between the chamber 410 and the enclosure 420. Either the chamber 410 or the enclosure 420 comprises groove(s) (e.g., 420G1) to accommodate the seal member 450. For example, the seal member 450 is disposed within the groove 420G1, which is located on the top of a side wall (e.g., 420W2 or 420W4) of the enclosure 420. Alternatively, the seal member 450 may be disposed in a groove at the bottom of the chamber 410.

The seal member 450 is designed to complement the groove 420G1. For example, as shown in FIG. 5, the seal member 450 and the groove 420G1 both feature a closed-loop shape substantially, albeit of different dimensions. When the fasteners 460 are tightened, their clamping pressure is applied to the seal member 450. The seal member 450 pressed may deform to fill the groove 420G1, thereby creating an effective seal that isolates the accommodation space 420S from the outside.

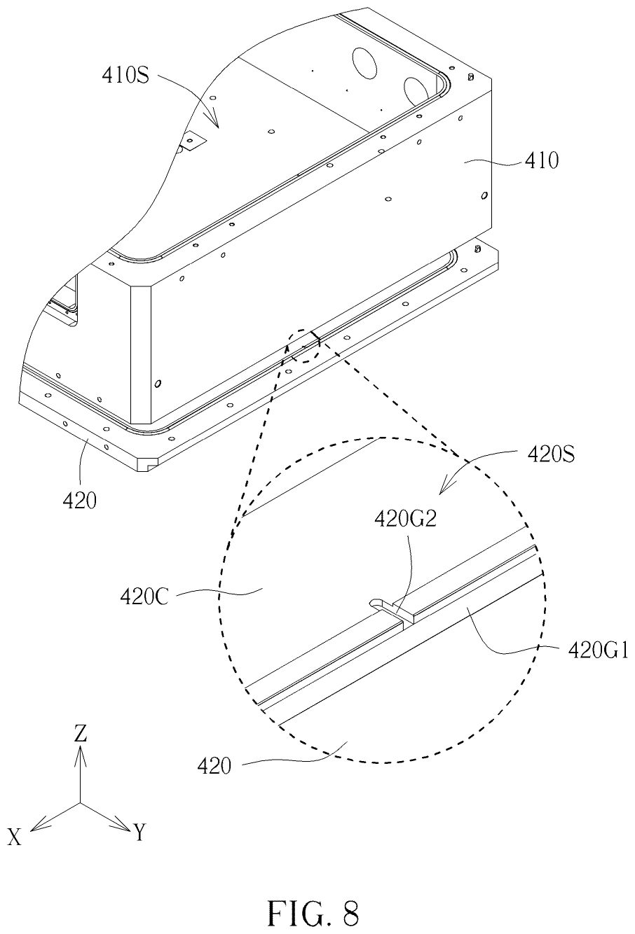

The groove's design may vary to facilitate the expulsion of excess gas. For example, as shown in FIG. 8, the groove 420G1 may extend inward, branching into an additional groove 420G2. Alternatively, the groove 420G2 can connect the groove 420G1 directly to the accommodation space 420S. Alternatively, the projection of a side wall (e.g., 410W2, 410W4, 420W2, or 420W4) onto a bottom wall (e.g., 410W1 or 420W1) completely overlaps the groove 420G1 but partially overlaps the groove 420G2. Alternatively, as shown in FIG. 7, the projection of the concavity 410C completely overlaps the groove 420G1 but partially overlaps the groove 420G2. In this manner, when the chamber 410 and the enclosure 420 are assembled, the side walls (e.g., 410W2 . . . or 420W4) form a secure seal, regardless of the pressure difference across the wall 420W1. Besides, non-solid substance(s) originally present in the groove 420G1 may be squeezed into the groove 420G2 or the accommodation space 420S during assembly, maintaining a reliable seal.

The seal member 450 and the fastener(s) 460 are strategically arranged to enhance sealing performance. For example, because leakage may occur near the fastener(s) 460, as shown in FIG. 5, the fastener(s) 460 are disposed outside the seal member 450 or the groove 420G1 to avoid potential leakage. This ensures a high-quality seal between the chamber 410 and the enclosure 420.

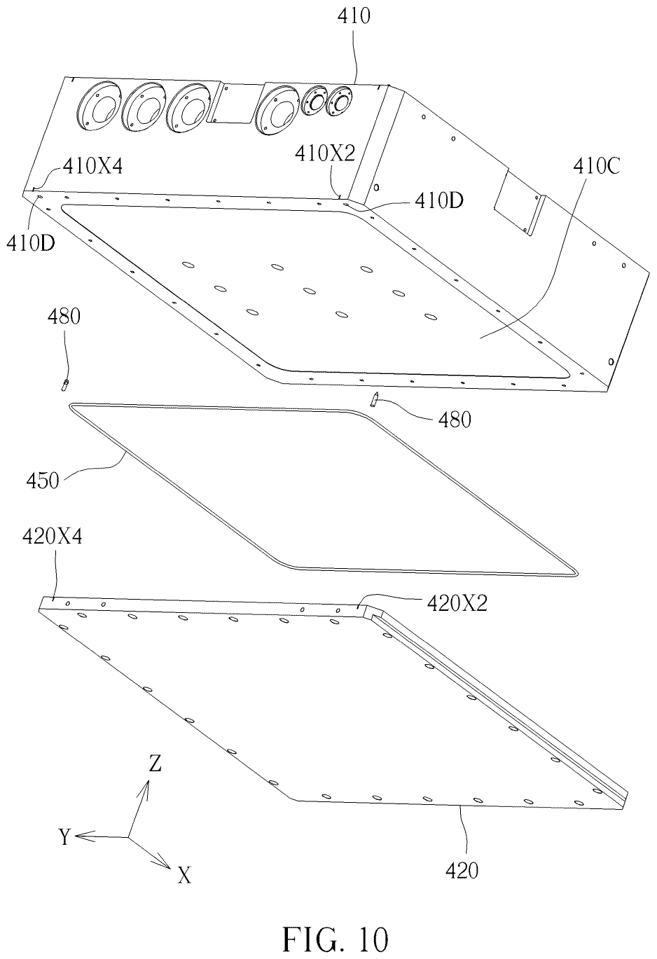

To assemble the chamber 410 and the enclosure 420 accurately and efficiently, their shape are carefully designed. For example, as shown in FIG. 10, which is an exploded-view drawing of the precision system 40, marks 410X2 and 410X4 on the chamber 410 are aligned with marks 420X2 and 420X4 on the enclosure 420 to facilitate the accurate attachment of the enclosure 420 to the chamber 410. Alternatively, each reconciler 480 may be inserted into a depression 410D on the chamber 410 and a depression 420D on the enclosure 420. The reconciler 480 may substantially feature the shape of a round-ended cylinder or rod, with varying diameters along its symmetric axis. Optionally, the enclosure 420 may comprise one or two depressions 420D instead of four depressions.

Details or modifications of a bottom chamber or a particle reducer are disclosed in U.S. application Ser. No. 18/988,956, the disclosure of which is hereby incorporated by reference herein in its entirety and made a part of this specification.

To sum up, apart from preventing static deformation from being transferred from the chamber to the precision parts inside, the added enclosure is easy to assemble and maintain. Moreover, it does not degrade dynamic performance (e.g., vibration) and temperature distribution of the precision parts.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A precision system, comprising:
a chamber, comprising a first wall and a second wall to create a first accommodation space, wherein at least one precision part is mounted, or is to be mounted, on the first wall inside the first accommodation space; and
an enclosure, wherein the enclosure and the chamber are assembled, or are to be assembled, to create a second accommodation space;
wherein the second accommodation space between the enclosure and the first wall connects to the first accommodation space;
wherein deformation of the first wall is substantially less than deformation of the second wall or the enclosure after pressure in the first accommodation space becomes different from pressure outside the precision system.

2. The precision system of claim 1, further comprising:
at least one pad, disposed within the second accommodation space on the enclosure;
wherein each pad forms a bar shape, with a longest side parallel to a largest surface of the first wall;
wherein each pad remains separated from the chamber until the pressure in the first accommodation space approaches to vacuum pressure.

3. The precision system of claim 1,
wherein at least one pad satisfies D3×0.85=D1−D2, where D3 represents thickness of one of the at least one pad without deformation, D1 represents distance between the first wall and a third wall of the enclosure, and D2 represents simulated deformation of the third wall;
wherein D2 is proportional to 1/T³, where T represents thickness of the third wall.

4. The precision system of claim 1, wherein
wherein Poisson's ratio of at least one pad is in the range of 0.4 to 0.5;
wherein damping coefficient of the at least one pad is higher than damping coefficient of the enclosure or the chamber; or
wherein thermal conductivity of the at least one pad is higher than thermal conductivity of vacuum or air.

5. The precision system of claim 1,
wherein the first wall comprises at least one hole;
wherein the first accommodation space connects to the second accommodation space via the at least one hole;
wherein at least one particle reducer, configured to attract charged particles or debris, is disposed corresponding to the at least one hole.

6. The precision system of claim 1,
wherein projection of at least one pad onto the first wall does not overlap at least one hole of the first wall;
wherein a maximum cross-section area of each pad is larger than size of each hole.

7. The precision system of claim 1, further comprising:
a seal member, configured to seal a gap between the chamber and the enclosure; and
at least one fastener, disposed outside the seal member and configured to mechanically secure the chamber and the enclosure together.

8. The precision system of claim 1,
wherein the enclosure or the chamber comprises a first groove and a second groove;
wherein the first groove forms a closed shape;
wherein a seal member is disposed, or is to be disposed, in the first groove;
wherein one end of the second groove is connected to the first groove to connect the first groove to the second accommodation space;
wherein projection of the second wall onto the enclosure completely overlaps the first groove and partially overlaps the second groove.

9. The precision system of claim 1,
wherein the enclosure comprises a third wall parallel to the first wall;
wherein thickness of the third wall is substantially not less than thickness of the first or second wall;
wherein a maximum cross-section area of the enclosure is substantially equal to or greater than a maximum cross-section area of the chamber.

10. The precision system of claim 1,
wherein the pressure outside the precision system is atmospheric pressure;
wherein the pressure of the first accommodation space is between vacuum pressure and a pressure higher than the atmospheric pressure;
wherein pressure difference between the first accommodation space and the second accommodation space is not greater than pressure difference between the first accommodation space and the atmospheric pressure.

11. An assembling method, for a precision system, comprising:
mounting at least one precision part on a first wall inside a chamber, wherein the chamber comprises the first wall and a second wall to create a first accommodation space; and
assembling an enclosure and the chamber of the precision system to create a second accommodation space;
wherein the second accommodation space between the enclosure and the first wall connects to the first accommodation space;
wherein deformation of the first wall is substantially less than deformation of the second wall or the enclosure after pressure in the first accommodation space becomes different from pressure outside the precision system.

12. The assembling method of claim 11,
wherein the precision system further comprises at least one pad, disposed within the second accommodation space on the enclosure;
wherein each pad forms a bar shape, with a longest side parallel to a largest surface of the first wall;
wherein each pad remains separated from the chamber until the pressure in the first accommodation space approaches to vacuum pressure.

13. The assembling method of claim 11,
wherein at least one pad satisfies D3×0.85=D1−D2, where D3 represents thickness of one of the at least one pad without deformation, D1 represents distance between the first wall and a third wall of the enclosure, and D2 represents simulated deformation of the third wall;
wherein D2 is proportional to 1/T³, where T represents thickness of the third wall.

14. The assembling method of claim 11,
wherein Poisson's ratio of at least one pad is in the range of 0.4 to 0.5;
wherein damping coefficient of the at least one pad is higher than damping coefficient of the enclosure or the chamber; or
wherein thermal conductivity of the at least one pad is higher than thermal conductivity of vacuum or air.

15. The assembling method of claim 11,
wherein the first wall comprises at least one hole;
wherein the first accommodation space connects to the second accommodation space via the at least one hole;
wherein at least one particle reducer, configured to attract charged particles or debris, is disposed corresponding to the at least one hole.

16. The assembling method of claim 11,
wherein projection of at least one pad onto the first wall does not overlap at least one hole of the first wall;
wherein a maximum cross-section area of each pad is larger than size of each hole.

17. The assembling method of claim 11, wherein the precision system further comprises:
a seal member, configured to seal a gap between the chamber and the enclosure; and
at least one fastener, disposed outside the seal member and configured to mechanically secure the chamber and the enclosure together.

18. The assembling method of claim 11,
wherein the enclosure or the chamber comprises a first groove and a second groove;
wherein the first groove forms a closed shape;
wherein a seal member is disposed, or is to be disposed, in the first groove;
wherein one end of the second groove is connected to the first groove to connect the first groove to the second accommodation space;
wherein projection of the second wall onto the enclosure completely overlaps the first groove and partially overlaps the second groove.

19. The assembling method of claim 11,
wherein the enclosure comprises a third wall parallel to the first wall;
wherein thickness of the third wall is substantially not less than thickness of the first or second wall;
wherein a maximum cross-section area of the enclosure is substantially equal to or greater than a maximum cross-section area of the chamber.

20. The assembling method of claim 11,
wherein the pressure outside the precision system is atmospheric pressure;
wherein the pressure of the first accommodation space is between vacuum pressure and a pressure higher than the atmospheric pressure;
wherein pressure difference between the first accommodation space and the second accommodation space is not greater than pressure difference between the first accommodation space and the atmospheric pressure.
